(19) United States
(12) Patent Application Publication
(10) Pub. No.: US 2025/0194170 A1
(43) Pub. Date: Jun. 12, 2025

(54) SEMICONDUCTOR STRUCTURE AND FABRICATING METHOD THEREOF

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/802,185

(22) Filed: Aug. 13, 2024

(30) Foreign Application Priority Data
Dec. 7, 2023 (CN) 202311674990.2

(51) Int. Cl. H01L 29/06; H01L 29/66; H01L 29/778

(52) U.S. Cl. CPC H10D 62/102; H10D 30/015; H10D 30/47

(57) ABSTRACT

Disclosed are a semiconductor structure and a fabricating method thereof. The semiconductor structure includes a substrate, a channel layer, a barrier layer, a first passivation layer, and a second passivation layer that are sequentially stacked; a through hole is disposed penetrating through the first passivation layer and the second passivation layer, and the through hole is filled with a semiconductor layer, where the semiconductor layer includes a P-type activation region and a first high-resistance region, and the P-type activation region is configured to deplete a 2DEG of a lower channel to implement an enhancement mode device; the first high-resistance region is located at an included angle formed by the P-type activation region and the barrier layer, so as to reduce a leakage current near the P-type activation region and improve a reliability of a device.

### CROSS-REFERENCE TO RELATED APPLICATIONS

The present disclosure claims priority to Chinese Patent Application No. 202311674990.2, filed on Dec. 7, 2023, all contents of which are incorporated herein in its entirety by reference.

### TECHNICAL FIELD

The present disclosure relates to the technical field of semiconductors, and in particular, to a semiconductor structure and a fabricating method thereof.

### BACKGROUND

Compared with a first-generation semiconductor material and a second-generation semiconductor material, a third-generation semiconductor material, especially a GaN-based material (gallium nitride) has advantages of wide band gap, high breakdown field strength, high electron mobility, strong radiation resistance, and the like. The GaN-based High Electron Mobility Transistor (HEMT) has great development potential in high-frequency and high-power fields such as wireless communication base stations, radars, automobile electronics, and the like.

In general, the GaN-based HEMT device is a depletion mode field effect transistor, for example, a negative turn-on voltage needs to be used in a radio frequency microwave application, which makes a circuit structure become complex and the anti-misoperation protection function of the circuit is also affected, and thereby a safety of the circuit is reduced, and therefore, it is necessary to carry out a research on an enhancement mode GaN-based HEMT device.

Common methods for implementing the enhancement mode device include trench gate technology, fluorine ion implantation technology, and P-type gate technology. In the P-type gate technology, a P-type GaN-based epitaxial layer is added between a gate metal and a barrier layer, so that a height of the barrier layer is reduced, a conduction band of a whole heterojunction rise above the Fermi level due to a conduction band difference between the P-type GaN-based epitaxial layer and the barrier layer, and the Two Dimensional Electron Gas (2DEG) at the channel below the gate is exhausted to achieve enhancement. However, in a fabricating process of the device, the P-type GaN-based epitaxial layer between a gate source and a gate drain needs to be etched away, it is difficult to control an etching precision, an etching damage is introduced, finally an output current density is reduced, a gate leakage current is increased, and the device stability is reduced.

### SUMMARY

In view of this, embodiments of the present disclosure provide a semiconductor structure and a fabricating method thereof.

In a first aspect, an embodiment of the present disclosure provides a semiconductor structure, including: a substrate, a channel layer, a barrier layer, a first passivation layer, and a second passivation layer sequentially stacked; a through hole penetrating through the first passivation layer and the second passivation layer, where a cross-sectional area of the through hole located in the first passivation layer is greater than a cross-sectional area of the through hole located in the second passivation layer; and a semiconductor layer located in the through hole, where the semiconductor layer includes a P-type activation region and a first high-resistance region, the P-type activation region penetrates through the first passivation layer and the second passivation layer, the first high-resistance region is located between the P-type activation region and the first passivation layer, and a projection, on the substrate, of the second passivation layer covers a projection, on the substrate, of the first high-resistance region.

In an embodiment of the present disclosure, a hydrogen concentration of the first high-resistance region is higher than a hydrogen concentration of the P-type activation region.

In an embodiment of the present disclosure, the second passivation layer is a single-layer structure and the single-layer structure includes any one of a SiN layer and an AlN layer; or, the second passivation layer is a multi-layer structure and the multi-layer structure includes a SiN layer and an AlN layer that are stacked.

In an embodiment of the present disclosure, when the second passivation layer includes the SiN layer, a hydrogen content of the SiN layer is 5% to 20%; and the semiconductor layer further includes a second high-resistance region, and the second high-resistance region is in contact with the SiN layer.

In an embodiment of the present disclosure, when the second passivation layer is a single-layer structure of the SiN layer, the second high-resistance region covers a side surface, close to the P-type activation region, of the second passivation layer.

In an embodiment of the present disclosure, when the second passivation layer is a multi-layer structure including the SiN layer and the AlN layer, the second high-resistance region is in contact with the SiN layer, and at least a part of the second high-resistance region covers a side surface, close to the P-type activation region, of the second passivation layer.

In an embodiment of the present disclosure, in a direction parallel to a plane where the substrate is located, a thickness of the second high-resistance region ranges from 1 nm to 50 nm.

In an embodiment of the present disclosure, a hydrogen concentration of the second high-resistance region is higher than a hydrogen concentration of the P-type activation region.

In an embodiment of the present disclosure, a material of the first passivation layer includes SiO₂.

In an embodiment of the present disclosure, a sidewall, close to the P-type activation region, of the second passivation layer is flush with a sidewall, close to the P-type activation region, of the first high-resistance region.

In an embodiment of the present disclosure, the semiconductor structure further includes a gate electrode located on a side, away from the substrate, of the P-type activation region, and a source electrode and a drain electrode located on a side, away from the substrate, of the channel layer, where the source electrode and the drain electrode are located on two sides of the gate electrode.

In an embodiment of the present disclosure, the first high-resistance region is located on a side, close to the drain electrode, of the P-type activation region.

In a second aspect, an embodiment of the present disclosure provides a fabricating method of a semiconductor structure, including: sequentially epitaxially fabricating a channel layer and a barrier layer on a substrate; fabricating, on the barrier layer, a first passivation layer and a second passivation layer having a through hole, where the through hole penetrates through the first passivation layer and the second passivation layer, and a cross-sectional area of the through hole located in the first passivation layer is greater than a cross-sectional area of the through hole located in the second passivation layer; selectively epitaxially fabricating a semiconductor material layer in the through hole; and performing an annealing treatment to convert the semiconductor material layer into a semiconductor layer, where the semiconductor layer includes a P-type activation region and a first high-resistance region, the P-type activation region penetrates through the first passivation layer and the second passivation layer, the first high-resistance region is located between the P-type activation region and the first passivation layer, and a projection, on the substrate, of the second passivation layer covers a projection, on the substrate, of the first high-resistance region.

In an embodiment of the present disclosure, the fabricating, on the barrier layer, a first passivation layer and a second passivation layer having a through hole includes: forming an initial through hole penetrating through the first passivation layer and the second passivation layer by performing a dry etching of the first passivation layer and the second passivation layer; and forming the through hole by performing a wet etching of the first passivation layer in the initial through hole.

In an embodiment of the present disclosure, the fabricating, on the barrier layer, a first passivation layer and a second passivation layer having a through hole includes: fabricating a first sacrificial layer on the barrier layer; depositing the first passivation layer on the first sacrificial layer and the barrier layer; performing a chemical mechanical polishing treatment on the first passivation layer until the first sacrificial layer is exposed; fabricating a second sacrificial layer on the first sacrificial layer, where a projection, on the substrate, of the first sacrificial layer covers a projection, on the substrate, of the second sacrificial layer; depositing the second passivation layer on the second sacrificial layer and the barrier layer; performing the chemical mechanical polishing treatment on the second passivation layer located on the second sacrificial layer until the second sacrificial layer is exposed; and removing the first sacrificial layer and the second sacrificial layer by etching to form the through hole.

In an embodiment of the present disclosure, the fabricating a first sacrificial layer on the barrier layer includes: fabricating the first sacrificial layer on the barrier layer by means of a full-surface deposition and a regional etching.

In an embodiment of the present disclosure, the depositing the first passivation layer on the first sacrificial layer and the barrier layer includes: fabricating the first passivation layer on the first sacrificial layer and the barrier layer by means of a full-surface deposition.

In an embodiment of the present disclosure, the fabricating a second sacrificial layer on the first sacrificial layer includes: fabricating the second sacrificial layer on the first sacrificial layer by means of a full-surface deposition and a regional etching.

In an embodiment of the present disclosure, a material of the first sacrificial layer is the same with a material of the second sacrificial layer.

In an embodiment of the present disclosure, the annealing treatment includes: treating at least 20 minutes in an N₂ atmosphere at 500° C. to 1000° C.

### BRIEF DESCRIPTION OF THE DRAWINGS

FIG. 1 is a schematic structural diagram of a semiconductor structure according to an embodiment of the present disclosure.

FIG. 2 is a schematic structural diagram of an intermediate structure according to an embodiment of the present disclosure.

FIG. 3 is a schematic structural diagram of another semiconductor structure according to an embodiment of the present disclosure.

FIG. 4 is a schematic structural diagram of still another semiconductor structure according to an embodiment of the present disclosure.

FIG. 5 is a schematic structural diagram of still another semiconductor structure according to an embodiment of the present disclosure.

FIG. 6 is a schematic structural diagram of still another semiconductor structure according to an embodiment of the present disclosure.

FIG. 7 is a schematic structural diagram of still another semiconductor structure according to an embodiment of the present disclosure.

FIG. 8 to FIG. 17 are intermediate structural diagrams of fabricating a semiconductor structure according to an embodiment of the present disclosure.

FIG. 18 is a schematic flowchart of a fabricating method of a semiconductor structure according to an embodiment of the present disclosure.

### DETAILED DESCRIPTION OF THE EMBODIMENTS

Technical solutions in the embodiments of the present disclosure will be clearly described below with reference to the accompanying drawings in the embodiments of the present disclosure. Apparently, the described embodiments are a part of the embodiments of the present disclosure, rather than all the embodiments.

In order to solve above problems, the present disclosure provides a semiconductor structure, including: a substrate, a channel layer, a barrier layer, a first passivation layer and a second passivation layer sequentially stacked; a through hole penetrating through the first passivation layer and the second passivation layer, where a cross-sectional area of the through hole located in the first passivation layer is greater than a cross-sectional area of the through hole located in the second passivation layer; and a semiconductor layer located in the through hole, where the semiconductor layer includes a P-type activation region and a first high-resistance region, the P-type activation region penetrates through the first passivation layer and the second passivation layer, the first high-resistance region is located between the P-type activation region and the first passivation layer, and a projection, on the substrate, of the second passivation layer covers a projection, on the substrate, of the first high-resistance region.

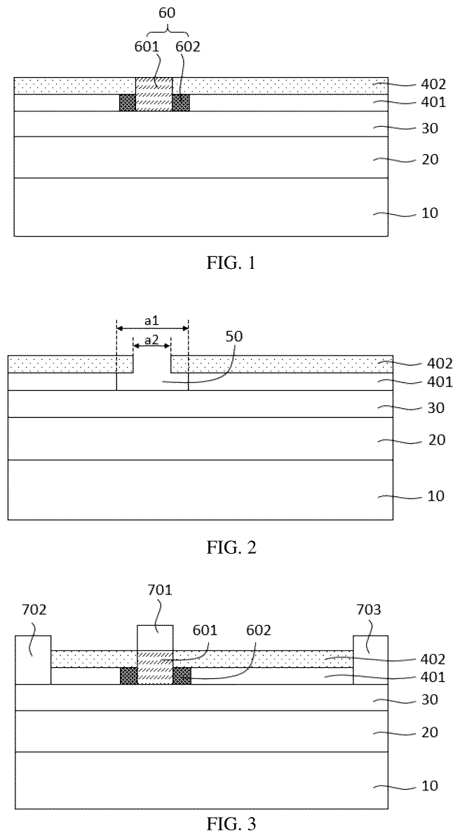

The semiconductor structure and a fabricating method thereof mentioned in the present disclosure are further illustrated below with reference to FIG. 1 to FIG. 17.

FIG. 1 is a schematic structural diagram of a semiconductor structure according to an embodiment of the present disclosure, and FIG. 2 is a schematic structural diagram of an intermediate structure according to an embodiment of the present disclosure. As shown in FIG. 1 and FIG. 2, the semiconductor structure includes: a substrate 10, a channel layer 20, a barrier layer 30, a first passivation layer 401, and a second passivation layer 402 that are sequentially stacked; a through hole 50 penetrates through the first passivation layer 401 and the second passivation layer 402, and a cross-sectional area of the through hole 50 located in the first passivation layer 401 is greater than a cross-sectional area of the through hole 50 located in the second passivation layer 402; a semiconductor layer located in the through hole 50, where the semiconductor layer 60 includes a P-type activation region 601 and a first high-resistance region 602, the P-type activation region 601 penetrates through the first passivation layer 401 and the second passivation layer 402, the first high-resistance region 602 is located between the P-type activation region 601 and the first passivation layer 401, and a projection, on the substrate 10, of the second passivation layer 402 covers a projection, on the substrate 10, of the first high-resistance region 602.

Specifically, as shown in FIG. 1 and FIG. 2, the through hole 50 penetrates through the first passivation layer 401 and the second passivation layer 402, in a longitudinal cross-section, a width a1 of the through hole 50 at the first passivation layer 401 is greater than a width a2 of the through hole 50 at the second passivation layer 402. Correspondingly, the semiconductor layer 60 is located in the through hole 50, and the width a1 of the semiconductor layer 60 at the first passivation layer 401 is greater than the width a2 of the semiconductor layer 60 at the second passivation layer 402; and the through hole 50 located in the first passivation layer 401 includes a first high-resistance region 602 and a part of a P-type activation region 601, and the through hole 50 located in the second passivation layer 402 only includes a remaining part of the P-type activation region 601.

Specifically, as shown in FIG. 1, the semiconductor layer 60 includes the P-type activation region 601 and a first high-resistance region 602, and the first high-resistance region 602 is located in a region covered by the second passivation layer 402, so that the projection, on the substrate 10, of the second passivation layer 402 covers the projection, on the substrate 10, of the first high-resistance region 602; a region in the semiconductor layer 60 that is not covered by the second passivation layer 402 is the P-type activation region 601, so that the P-type activation region 601 penetrates through the first passivation layer 401 and the second passivation layer 402. In other words, the cross-sectional area of the through hole 50 located in the second passivation layer 402 is equal to a projection, on the substrate 10, area of the P-type activation region 601; the cross-sectional area of the through hole 50 located in the first passivation layer 401 minus the cross-sectional area of the through hole 50 located in the second passivation layer 402 is equal to a projection, on the substrate 10, area of the first high-resistance region 602.

Specifically, the channel layer 20 and the barrier layer 30 constitute a heterojunction, and a channel with 2DEG is formed on a surface, close to the barrier layer 30, of the channel layer 20, and when the semiconductor device is in an off-state, the P-type activation region 601 may deplete the 2DEG at the channel to implement an enhancement mode device; the first high-resistance region 602 is located between the P-type activation region 601 and the first passivation layer 401, and is covered by the projection of the second passivation layer 402 on the substrate 10, the first high-resistance region 602 is located at an included angle formed by the P-type activation region 601 and the barrier layer 30, and the first high-resistance region may share a leakage current or an electric field strength near the P-type activation region, thereby reducing the leakage current near the P-type activation region and improving a reliability of the device.

Optionally, the semiconductor structure uses a GaN-based semiconductor material, for example, a material of the channel layer 20 is GaN, and a material of the barrier layer 30 is AlGaN. Optionally, a material of the substrate 10 is selected from any one of monocrystalline silicon, monocrystalline germanium, sapphire, diamond, SiC, and GaN.

Optionally, as shown in FIG. 1, a sidewall, close to the P-type activation region 601, of the second passivation layer 402 is flush with a sidewall, close to the P-type activation region 601, of the first high-resistance region 602. It may be understood that, when activated to form the P-type activation region 601, the first high-resistance region 602 and the second passivation layer 402 have coplanar sidewalls due to a blocking of H atoms by the second passivation layer 402.

In an embodiment, a hydrogen concentration of the first high-resistance region 602 is higher than a hydrogen concentration of the P-type activation region 601, so that a resistivity of the first high-resistance region 602 is greater than a resistivity of the P-type activation region 601, and the first high-resistance region 602 is used for reducing the leakage current near the P-type activation region 601. Specifically, the P-type activation region 601 and the first high-resistance region 602 are simultaneously formed in an annealing treatment, a Mg—H bond in the P-type activation region 601 is disconnected, an H atom escapes, a Mg is released, and the P-type activation region 601 is presented as a P-type conductivity type. Meanwhile, due to the blocking of the second passivation layer 402, the H atom cannot escape, the Mg—H bond in the first high-resistance region 602 is kept in a bond state, and compared with the P-type activation region 601, the first high-resistance region 602 is presented as a high-resistance state.

It should be noted that the hydrogen concentration refers to the number of H atoms in a unit volume.

In an embodiment, FIG. 3 is a schematic structural diagram of another semiconductor structure according to an embodiment of the present disclosure. As shown in FIG. 3, the semiconductor structure further includes: a gate electrode 701 located on a side, away from the substrate 10, of the P-type activation region 601, a source electrode 702 and a drain electrode 703 located on a side, away from the substrate 10, of the channel layer 20, and the source electrode 702 and the drain electrode 703 are located on two sides of the gate electrode 701. Specifically, as shown in FIG. 3, the source electrode 702 and the drain electrode 703 are located above the barrier layer 30, and the source electrode 702 and the drain electrode 703 respectively form an ohmic contact with the barrier layer 30; optionally, the source electrode 702 and the drain electrode 703 penetrate through the barrier layer 30 to form the ohmic contact with the channel layer 20 (not shown).

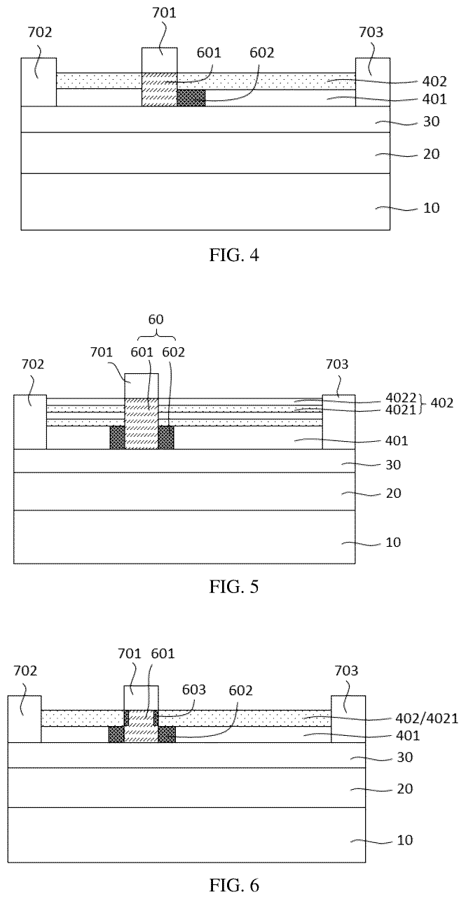

In an embodiment, FIG. 4 is a schematic structural diagram of still another semiconductor structure according to an embodiment of the present disclosure. As shown in FIG. 4, the first high-resistance region 602 is located on a side, close to the drain electrode 703, of the P-type activation region 601. Specifically, an electric field strength on a side, close to the drain electrode 703, of the gate electrode 701 is larger, the first high-resistance region 602 may reduce the electric field strength, and a withstand voltage value of the semiconductor structure is improved; and in an off-state, the leakage current may be reduced in the first high-resistance region 602.

In an embodiment, as shown in FIG. 1 and FIG. 3, the second passivation layer 402 is a single-layer structure, the single-layer structure includes any one of a SiN layer and an AlN layer, and a material of the second passivation layer 402 is SiN or AlN. Alternatively, FIG. 5 is a schematic structural diagram of still another semiconductor structure according to an embodiment of the present disclosure. As shown in FIG. 5, the second passivation layer 402 is a multi-layer structure, and the multi-layer structure includes a SiN layer 4021 and an AlN layer 4022 that are stacked. Specifically, whether the second passivation layer 402 is the single-layer structure or the multi-layer structure, a cross-sectional area of the through hole in the second passivation layer 402 is small, and in the annealing treatment of the semiconductor layer 60, the semiconductor layer 60 not covered by the second passivation layer 402 is activated to form the P-type activation region 601, and the semiconductor layer 60 covered by the second passivation layer 402 is not activated to maintain the high-resistance state, which is the first high-resistance region 602.

It should be noted that when the second passivation layer 402 is the multi-layer structure, especially a two-layer structure, it is maybe that the SiN layer 4021 is located between the AlN layer 4022 and the first passivation layer 401, or maybe that the AIN layer 4022 is located between the SiN layer 4021 and the first passivation layer 401. Optionally, a thickness of the SiN layer 4021 and the AlN layer 4022 is not limited. Optionally, when the second passivation layer 402 is the multi-layer structure with a number of layers greater than 2, a film layer closest to the first passivation layer 401 in the second passivation layer 402 may be the SiN layer 4021 or the AlN layer 4022.

In an embodiment, a material of the first passivation layer 401 includes SiO₂. Specifically, the material of the first passivation layer 401 is SiO₂, the material of the second passivation layer 402 is SiN and/or AlN, the material of the first passivation layer 401 is different from the material of the second passivation layer 402, and the through hole 50 may be fabricated by first dry etching and then wet etching. Optionally, the material of the first passivation layer 401 and the material of the second passivation layer 402 are SiN, and the through hole 50 may be fabricated by removing the sacrificial layer.

In an embodiment, FIG. 6 is a schematic structural diagram of still another semiconductor structure according to an embodiment of the present disclosure. As shown in FIG. 6, when a second passivation layer 402 includes a SiN layer, a hydrogen content of the SiN layer is 5% to 20%; and a semiconductor layer 60 further includes a second high-resistance region 603, and the second high-resistance region 603 is in contact with the SiN layer. Specifically, a hydrogen content of the SiN layer is 5% to 20%, and in an annealing treatment, H in the SiN layer is reversely diffused into a P-type activation region 601, so that free Mg is bonded to the H in a surface, close to the second passivation layer 402, of the P-type activation region 601, and finally the second high-resistance region 603 with a high-resistance state is formed between the P-type activation region 601 and the second passivation layer 402, the second high-resistance region 603 may reduce the leakage current near a P-type activation region 601 and further improving a reliability of the device.

It should be noted that the hydrogen content in the SiN is 5% to 20%, which means that a percentage of H atoms is between 5% and 20%.

Optionally, a hydrogen concentration of the second high-resistance region 603 is higher than a hydrogen concentration of the P-type activation region 601. Optionally, the second high-resistance region 603 also retains a portion of Mgs that are not bonded to the H, and the hydrogen concentration of the second high-resistance region 603 is between the hydrogen concentration of the P-type activation region 601 and a hydrogen concentration of the first high-resistance region 602, so that an electric field strength near the P-type activation region in an on-state may be reduced, and a withstand voltage value of the semiconductor structure is improved. Optionally, since the second passivation layer 402 blocks H atoms, the hydrogen concentration of the first high-resistance region 602 is equal to the second high-resistance region 603.

Optionally, as shown in FIG. 6, when the second passivation layer 402 is a single-layer structure of the SiN layer, the second high-resistance region 603 covers a side surface, close to the P-type activation region 601, of the second passivation layer 402. Specifically, when the second passivation layer 402 is a single-layer structure of the SiN layer, the first high-resistance region 602 covers a side surface, adjacent to the first passivation layer 401, of the P-type activation region 601, the second high-resistance region 603 covers a side surface, adjacent to the second passivation layer 402, of the P-type activation region 601, and a side surface of the P-type activation region 601 is covered by a semiconductor with a high-resistance state, so that the gate leakage current in the off-state may be reduced, and a withstand voltage value of the semiconductor structure during the on-state is improved.

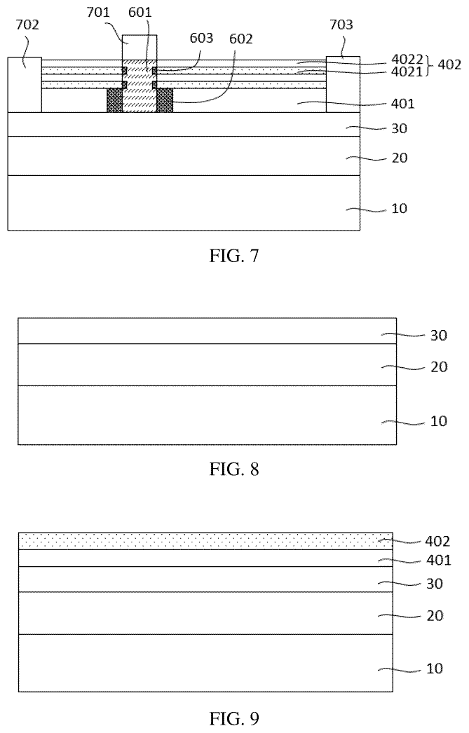

In an embodiment, FIG. 7 is a schematic structural diagram of still another semiconductor structure according to an embodiment of the present disclosure. As shown in FIG. 7, when a second passivation layer 402 is a multi-layer structure including a SiN layer 4021 and an AlN layer 4022, a second high-resistance region 603 is in contact with the SiN layer 4021, and at least a part of the second high-resistance region covers a side surface, close to a P-type activation region 601, of the second passivation layer 402. Specifically, as shown in FIG. 7, the second high-resistance region 603 is located between a side surface of the P-type activation region 601 and the SiN layer 4021, the number of the SiN layers 4021 corresponds to the number of the second high-resistance regions 603, and a plurality of second high-resistance regions 603 arranged at intervals on a side surface of the P-type activation region 601 may improve an electric field strength near the P-type activation region 601.

In an embodiment, in a direction parallel to a plane where the substrate 10 is located, a thickness of the second high-resistance region 603 ranges from 1 nm to 50 nm.

An embodiment of the present disclosure further provides a fabricating method of a semiconductor structure, and FIG. 8 to FIG. 17 are intermediate structural diagrams of fabricating a semiconductor structure according to an embodiment of the present disclosure. The method includes:

Step S1, as shown in FIG. 8 and FIG. 18, sequentially epitaxially fabricating a channel layer 20 and a barrier layer 30 on a substrate 10. Specifically, before the channel layer 20 is epitaxially fabricated, a nucleation layer and a buffer layer are first epitaxially fabricated on the substrate 10 to improve a crystal quality of a subsequent epitaxial fabrication.

Step S2, as shown in FIG. 2 and FIG. 18, fabricating a first passivation layer 401 and a second passivation layer 402 having a through hole 50 on the barrier layer 30, where the through hole 50 penetrates through the first passivation layer 401 and the second passivation layer 402, and a cross-sectional area of the through hole 50 located in the first passivation layer 401 is greater than a cross-sectional area of the through hole 50 located in the second passivation layer 402. Specifically, the first passivation layer 401 and the second passivation layer 402 having the through hole 50 are fabricated on the barrier layer 30 in following two manners.

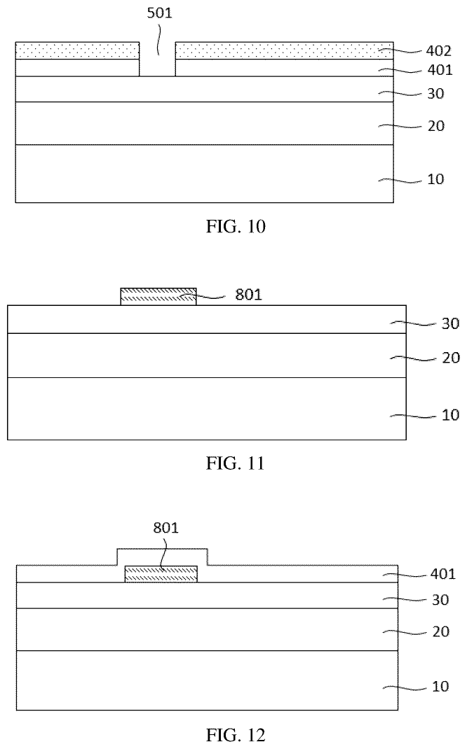

In a first manner, as shown in FIG. 9 and FIG. 10, forming an initial through hole 501 penetrating through the first passivation layer 401 and the second passivation layer 402 by performing a dry etching of the first passivation layer 401 and the second passivation layer 402. Specifically, a cross-sectional area of the initial through hole 501 located in the first passivation layer 401 is equal to a cross-sectional area of the initial through hole 501 located in the second passivation layer 402.

As shown in FIG. 2, forming the through hole 50 by performing a wet etching of the first passivation layer 401 in an initial through hole 501. Specifically, materials of the first passivation layer 401 and the second passivation layer 402 are different, in the wet etching process, an etching rate of the first passivation layer 401 is greater than an etching rate of the second passivation layer 402, or only the first passivation layer 401 is etched, so that the cross-sectional area of the through hole 50 located in the first passivation layer 401 is greater than the cross-sectional area of the through hole 50 located in the second passivation layer 402. It should be noted that, due to the first passivation layer 401 is etched by the wet etching process, a sidewall of the through hole 50 located in the first passivation layer 401 may be arc-shaped (not shown).

In a second manner, as shown in FIG. 11, fabricating the first sacrificial layer 801 on the barrier layer 30. Optionally, a first sacrificial layer 801 is fabricated by means of a full-surface deposition and a regional etching.

As shown in FIG. 12, depositing the first passivation layer 401 on the first sacrificial layer 801 and the barrier layer 30. Specifically, the first passivation layer 401 is full-surface deposited on the first sacrificial layer 801 and the barrier layer 30.

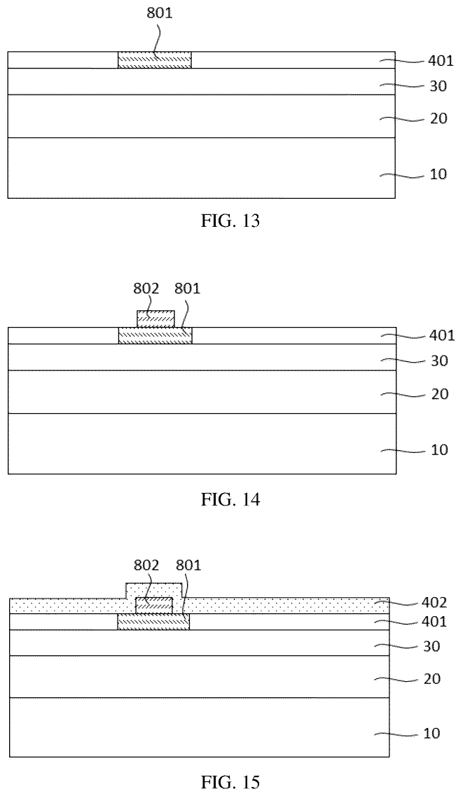

As shown in FIG. 13, performing a chemical mechanical polishing treatment on the first passivation layer 401 on the first sacrificial layer 801 until the first sacrificial layer 801 is exposed. Specifically, the chemical mechanical polishing treatment may make the processing surface smoother.

As shown in FIG. 14, fabricating a second sacrificial layer 801 on the first sacrificial layer 802, where a projection of the first sacrificial layer 801 on a substrate 10 covers a projection of the second sacrificial layer 802 on a substrate 10. Optionally, the second sacrificial layer 802 is fabricated by means of the full-surface deposition and the regional etching.

As shown in FIG. 15, depositing the second passivation layer 402 on the second sacrificial layer 802 and the barrier layer 30. Specifically, the second passivation layer 402 is deposited on the second sacrificial layer 802 and the barrier layer 30 by means of the full-surface deposition.

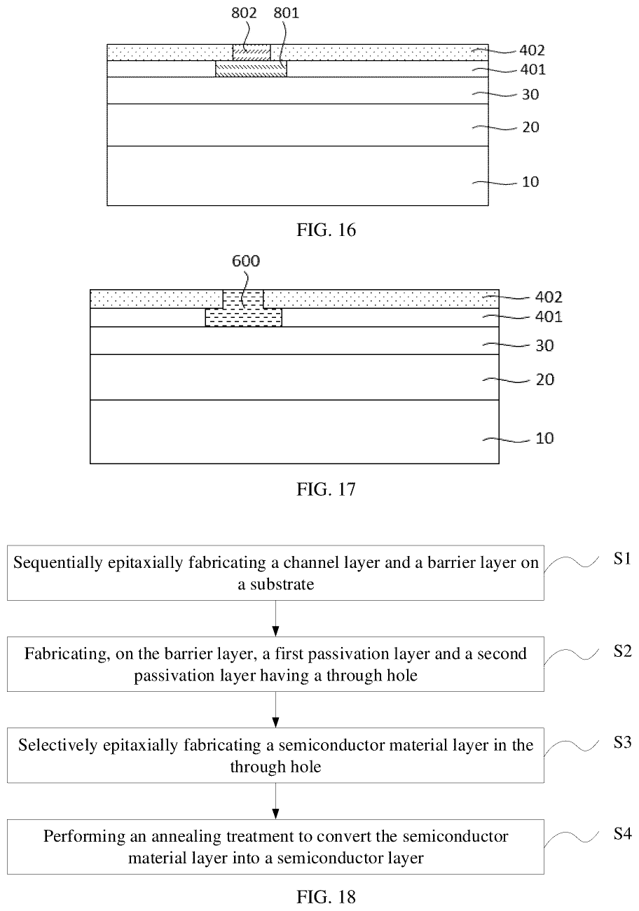

As shown in FIG. 16, performing the chemical mechanical polishing treatment on the second passivation layer 402 located on the second sacrificial layer 802 until the second sacrificial layer 802 is exposed.

As shown in FIG. 2, removing the first sacrificial layer 801 and the second sacrificial layer 802 by etching to form the through hole 50. Optionally, a material of the first sacrificial layer 801 is the same with a material of the second sacrificial layer 802.

Step S3, as shown in FIG. 17 and FIG. 18, selectively epitaxially fabricating a semiconductor material layer 600 in the through hole 50. Optionally, the semiconductor material layer 600 fills the entire through hole 50.

Step S4, as shown in FIG. 1 and FIG. 18, performing an annealing treatment to convert the semiconductor material layer 600 into a semiconductor layer 60, where the semiconductor layer 60 includes a P-type activation region 601 and a first high-resistance region 602, the P-type activation region 601 penetrates through a first passivation layer 401 and a second passivation layer 402, the first high-resistance region 602 is located between the P-type activation region 601 and the first passivation layer 401, and a projection of the second passivation layer 402 on a substrate 10 covers a projection of the first high-resistance region 602 on a substrate 10. Specifically, the annealing treatment may cause a Mg—H bond located in a region of the P-type activation region 601 in the semiconductor material layer 600 to be disconnected, an H atom escapes, a Mg is released, the P-type conductivity type is presented. Meanwhile, due to a blocking of the second passivation layer 402, the H atom cannot escape, the Mg—H bond located in a region of the first high-resistance region 602 is kept in a bond state, and compared with the P-type activation region 601, a free state Mg of the first high-resistance region 602 is less, and is presented as a high-resistance state.

Optionally, as shown in FIG. 1, a sidewall, close to the P-type activation region 601, of the second passivation layer 402 is flush with a sidewall, close to the P-type activation region 601, of the first high-resistance region 602.

Optionally, the annealing treatment includes: treating at least 20 minutes in an N₂ atmosphere at 500° C. to 1000° C., so that the P-type activation region 601 is activated to form a P-type conductivity type.

Optionally, as shown in FIG. 6 and FIG. 7, a second passivation layer 402 includes a SiN layer 4021, and a hydrogen content of the SiN layer 4021 ranges from 5% to 20%. A semiconductor layer 60 further includes a second high-resistance region 603 adjacent to the SiN layer 4021. Specifically, in the annealing treatment, a H in the SiN layer 4021 enters the P-type activation region 601, so that a region, adjacent to the SiN layer 4021, of the P-type activation region 601 is passivated to form the second high-resistance region 603, and a hydrogen concentration of the second high-resistance region 603 is higher than a hydrogen concentration of the P-type activation region 601.

The present disclosure provides a semiconductor structure and a fabricating method thereof, and the semiconductor structure includes a substrate, a channel layer, a barrier layer, a first passivation layer, and a second passivation layer that are sequentially stacked. A through hole is disposed penetrating through the first passivation layer and the second passivation layer, a cross-sectional area of the through hole located in the first passivation layer is greater than a cross-sectional area of the through hole located in the second passivation layer, and the through hole is filled with a semiconductor layer, where the semiconductor layer includes a P-type activation region and a first high-resistance region, the P-type activation region penetrates through the first passivation layer and the second passivation layer, and the P-type activation region is configured to deplete a 2DEG of a lower channel to implement an enhancement mode device; the first high-resistance region is located between the P-type activation region and the first passivation layer, and is covered by a projection of the second passivation layer on the substrate, and the first high-resistance region is located at an included angle formed by the P-type activation region and the barrier layer, so as to reduce a leakage current near the P-type activation region and improve a reliability of a device.

It should be understood that the terms “include” and variations thereof used in the present disclosure are open ended, that is, “including, but not limited to”. The term “one embodiment” means “at least one embodiment”. In this specification, the specific features, structures, materials, or characteristics described may be combined in any suitable manner in any one or more embodiments or examples. In addition, in the case of no contradiction, a person skilled in the art may combine and bond different embodiments or examples and features from different embodiments or examples described in the present disclosure.

What is claimed is:

1. A semiconductor structure, comprising:
a substrate, a channel layer, a barrier layer, a first passivation layer, and a second passivation layer sequentially stacked;
a through hole penetrating through the first passivation layer and the second passivation layer, wherein a cross-sectional area of the through hole located in the first passivation layer is greater than a cross-sectional area of the through hole located in the second passivation layer; and
a semiconductor layer located in the through hole,
wherein the semiconductor layer comprises a P-type activation region and a first high-resistance region, the P-type activation region penetrates through the first passivation layer and the second passivation layer, the first high-resistance region is located between the P-type activation region and the first passivation layer, and a projection, on the substrate, of the second passivation layer covers a projection, on the substrate, of the first high-resistance region.

2. The semiconductor structure according to claim 1, wherein a hydrogen concentration of the first high-resistance region is higher than a hydrogen concentration of the P-type activation region.

3. The semiconductor structure according to claim 1, wherein the second passivation layer is a single-layer structure and the single-layer structure comprises any one of a SiN layer and an AlN layer; or,
the second passivation layer is a multi-layer structure and the multi-layer structure comprises a SiN layer and an AIN layer that are stacked.

4. The semiconductor structure according to claim 3, wherein when the second passivation layer comprises the SiN layer, a hydrogen content of the SiN layer is 5% to 20%; and
the semiconductor layer further comprises a second high-resistance region, and the second high-resistance region is in contact with the SiN layer.

5. The semiconductor structure according to claim 4, wherein when the second passivation layer is a single-layer structure of the SiN layer, the second high-resistance region covers a side surface, close to the P-type activation region, of the second passivation layer.

6. The semiconductor structure according to claim 4, wherein when the second passivation layer is a multi-layer structure comprising the SiN layer and the AlN layer, the second high-resistance region is in contact with the SiN layer, and at least a part of the second high-resistance region covers a side surface, close to the P-type activation region, of the second passivation layer.

7. The semiconductor structure according to claim 4, wherein in a direction parallel to a plane where the substrate is located, a thickness of the second high-resistance region ranges from 1 nm to 50 nm.

8. The semiconductor structure according to claim 4, wherein a hydrogen concentration of the second high-resistance region is higher than a hydrogen concentration of the P-type activation region.

9. The semiconductor structure according to claim 1, wherein a material of the first passivation layer comprises SiO₂.

10. The semiconductor structure according to claim 1, wherein a sidewall, close to the P-type activation region, of the second passivation layer is flush with a sidewall, close to the P-type activation region, of the first high-resistance region.

11. The semiconductor structure according to claim 1, further comprising:
a gate electrode located on a side, away from the substrate, of the P-type activation region, and
a source electrode and a drain electrode located on a side, away from the substrate, of the channel layer, wherein the source electrode and the drain electrode are located on two sides of the gate electrode.

12. The semiconductor structure according to claim 11, wherein the first high-resistance region is located on a side, close to the drain electrode, of the P-type activation region.

13. A fabricating method of a semiconductor structure, comprising:
sequentially epitaxially fabricating a channel layer and a barrier layer on a substrate;
fabricating, on the barrier layer, a first passivation layer and a second passivation layer having a through hole, wherein the through hole penetrates through the first passivation layer and the second passivation layer, and a cross-sectional area of the through hole located in the first passivation layer is greater than a cross-sectional area of the through hole located in the second passivation layer;
selectively epitaxially fabricating a semiconductor material layer in the through hole; and
performing an annealing treatment to convert the semiconductor material layer into a semiconductor layer, wherein the semiconductor layer comprises a P-type activation region and a first high-resistance region, the P-type activation region penetrates through the first passivation layer and the second passivation layer, the first high-resistance region is located between the P-type activation region and the first passivation layer, and a projection, on the substrate, of the second passivation layer covers a projection, on the substrate, of the first high-resistance region.

14. The fabricating method according to claim 13, wherein the fabricating, on the barrier layer, a first passivation layer and a second passivation layer having a through hole comprises:
forming an initial through hole penetrating through the first passivation layer and the second passivation layer by performing a dry etching of the first passivation layer and the second passivation layer; and
forming the through hole by performing a wet etching of the first passivation layer in the initial through hole.

15. The fabricating method according to claim 13, wherein the fabricating, on the barrier layer, a first passivation layer and a second passivation layer having a through hole comprises:
fabricating a first sacrificial layer on the barrier layer;
depositing the first passivation layer on the first sacrificial layer and the barrier layer;
performing a chemical mechanical polishing treatment on the first passivation layer until the first sacrificial layer is exposed;
fabricating a second sacrificial layer on the first sacrificial layer, wherein a projection, on the substrate, of the first sacrificial layer covers a projection, on the substrate, of the second sacrificial layer;
depositing the second passivation layer on the second sacrificial layer and the barrier layer;
performing the chemical mechanical polishing treatment on the second passivation layer located on the second sacrificial layer until the second sacrificial layer is exposed; and
removing the first sacrificial layer and the second sacrificial layer by etching to form the through hole.

16. The fabricating method according to claim 15, wherein the fabricating a first sacrificial layer on the barrier layer comprises:
fabricating the first sacrificial layer on the barrier layer by means of a full-surface deposition and a regional etching.

17. The fabricating method according to claim 15, wherein the depositing the first passivation layer on the first sacrificial layer and the barrier layer comprises:
fabricating the first passivation layer on the first sacrificial layer and the barrier layer by means of a full-surface deposition.

18. The fabricating method according to claim 15, wherein the fabricating a second sacrificial layer on the first sacrificial layer comprises:
fabricating the second sacrificial layer on the first sacrificial layer by means of a full-surface deposition and a regional etching.

19. The fabricating method according to claim 15, wherein a material of the first sacrificial layer is the same with a material of the second sacrificial layer.

20. The fabricating method according to claim 13, wherein the annealing treatment comprises: treating at least 20 minutes in an N₂ atmosphere at 500° C. to 1000° C.
